(19) United States
(12) Patent Application Publication
(10) Pub. No.: US 2015/0090684 A1
(43) Pub. Date: Apr. 2, 2015

(54) LIFTING DEVICE AND AUTOMATIC HANDLING SYSTEM THEREOF

(71) Applicant: INOTERA MEMORIES, INC., Taoyuan County (TW)

(72) Inventors: HUAN-CHI LIAO, TAOYUAN COUNTY (TW); SHENG-JUNG CHANG, NEW TAIPEI CITY (TW)

(73) Assignee: INOTERA MEMORIES, INC., Taoyuan County (TW)

(21) Appl. No.: 14/108,620

(22) Filed: Dec. 17, 2013

(30) Foreign Application Priority Data
Sep. 27, 2013 (TW) 102135014

(51) Int. Cl. H01L 21/677; B66C 19/00

(52) U.S. Cl. CPC H01L 21/67763; B66C 19/00
USPC 212/276

(57) ABSTRACT

The instant disclosure relates to a lifting device for transporting a wafer carrier to an automatic handling system including a suspension rail and an automatic guiding vehicle configured to move along the suspension rail, comprising an elevating holder, a plurality of suspension modules, and a plurality of first drive modules. Specially, the elevating holder has a motion sensor configured to detect whether the elevating holder is in a horizontal state or a non-horizontal state. The first drive modules can be used to synchronously drive the suspension modules according the horizontal state detected by the motion sensor, and the first drive modules can also be used to individually drive each of the suspension modules according the non-horizontal state detected by the motion sensor to recover the elevating holder from the non-horizontal state as the horizontal state.

### BACKGROUND OF THE INVENTION

1. Field of the Invention

The instant disclosure relates to a lifting device; in particular, to a lifting device for transporting wafer carriers of semiconductor wafer fab and an automatic handling system thereof.

2. Description of Related Art

With the continuous improvement of wafer process as well as considering economies of scale and cost efficiency, wafer surface area is increased from 300 mm to 450 mm. In the future, silicon wafers must be developed to have a larger surface area. Thus, operator cannot directly transport wafers so that wafer transportation must rely on an auto-transporting device or system. Accordingly, the working efficiency of the auto-transporting device or system will directly affect the throughput of semiconductor fab. Therefore, in order to meet the throughput requirement, the transporting device or system need to maintain high stability and high performance.

Generally, semiconductor fab now utilizing an automatic guiding vehicle (AGV) slidably coupled to a suspension rail and a utilizing suspension type device operatively connected to the AGV to transport wafers. Concretely speaking, the suspension type device can elevate a wafer carrier such as FOUP from a load port of a processing tool to an overhead position by suspension elements such as timing belts. The AGV then deliver the wafer carrier to another processing tool along the suspension rail.

However, a swaying motion of the parts of the lifting device for grasping wafer carriers or an irregular suspension of the suspension elements of the lifting device may cause abnormal state of the AGV. The reason is that there is an alignment requirement between the parts and a wafer carrier, and the irregular suspension of the suspension elements can cause alignment failure. Moreover, if the suspension elements of the lifting device take a long time to elevate or lower wafer carriers, the parts of the lifting device cannot smoothly grasp a wafer carrier due to the non-horizontal state thereof caused by elastic fatigue of at least one of the suspension elements.

In consquence, the AGV can only stay at this time for trouble shooting such that overall transport time will be increased because of the traffic jam that other AGVs are blocked. Although regular maintenance of the AGV can reduce the frequency of the abnormal events, but these condition may still affect the throughput of semiconductor fab.

### SUMMARY OF THE INVENTION

The object of the instant disclosure is to provide a lifting device and an automatic handling system thereof. Said lifting device with auto-horizontal adjusting and positioning functions can prevent the automatic guiding vehicle from shutdown due to an irregular suspension or an alignment failure, thereby improving the overall efficiency of the automatic handling system.

In order to achieve the aforementioned objects, the lifting device according to a preferred embodiment of the instant disclosure is used for transporting a wafer carrier to an automatic handling system including a suspension rail and an automatic guiding vehicle configured to move along the suspension rail. The lifting device comprises an elevating holder, a plurality of suspension modules, and a plurality of first drive modules.

The elevating holder is arranged below the automatic guiding vehicle, having a motion sensor configured to detect whether the elevating holder is in a horizontal state or a non-horizontal state. The suspension modules are arranged on the automatic guiding vehicle for suspensively supporting the elevating holder. The first drive modules are configured to connect the suspension modules respectively. Specially, the first drive modules can be used to synchronously drive the suspension modules according the horizontal state detected by the motion sensor, and the first drive modules can also be used to individually drive each of the suspension modules according the non-horizontal state detected by the motion sensor to recover the elevating holder from the non-horizontal state as the horizontal state.

According to the lifting device, the instant disclosure further provides an automatic handling system, comprising a suspension rail, at least one automatic guiding vehicle, and at least one lifting device. The automatic guiding vehicle is configured to move along the suspension rail for transporting a wafer carrier between different processing tools. The lifting device is configured to connect the automatic guiding vehicle, comprising an elevating holder, a plurality of suspension modules, and a plurality of first drive modules.

The elevating holder is arranged below the automatic guiding vehicle, having a motion sensor configured to detect whether the elevating holder is in a horizontal state or a non-horizontal state. The suspension modules are arranged on the automatic guiding vehicle for suspensively supporting the elevating holder. The first drive modules are configured to connect the suspension modules respectively. Specially, the first drive modules can be used to synchronously drive the suspension modules according the horizontal state detected by the motion sensor, and the first drive modules can also be used to individually drive each of the suspension modules according the non-horizontal state detected by the motion sensor to recover the elevating holder from the non-horizontal state as the horizontal state.

Base on above, the lifting device utilizing the first drive modules to drive the suspension modules one to one by. arranging the motion sensor together, having the function of auto-horizontal adjusting. Therefore, the lifting device can prevent the automatic handling system thereof from shutdown due to a non-horizontal state during the transporting procedures.

In order to further appreciate the characteristics and technical contents of the instant disclosure, references are hereunder made to the detailed descriptions and appended drawings in connection with the instant disclosure. However, the appended drawings are merely shown for exemplary purposes, rather than being used to restrict the scope of the instant disclosure.

### BRIEF DESCRIPTION OF THE DRAWINGS

FIG. 1 shows a three-dimensional drawing of an automatic handling system according to a first embodiment of the instant disclosure;

FIG. 2 shows a three-dimensional drawing of a lifting device according to a first embodiment of the instant disclosure;

FIG. 3-5 are views showing the auto-horizontal adjusting procedure of the lifting device according to a first embodiment of the instant disclosure;

FIG. 6 shows a three-dimensional drawing of a lifting device according to a second embodiment of the instant disclosure; and

FIGS. 7 and 8 are views showing the alignment procedure of the lifting device with the wafer carrier according to a second embodiment of the instant disclosure.

### DETAILED DESCRIPTION OF THE PREFERRED EMBODIMENTS

The aforementioned illustrations and following detailed descriptions are exemplary for the purpose of further explaining the scope of the instant disclosure. Other objectives and advantages related to the instant disclosure will be illustrated in the subsequent descriptions and appended drawings.

The instant disclosure provides a lifting device for semiconductor wafer fab and an automatic handling system including the lifting device. Specially, the lifting device with auto-positioning and auto-horizontal adjusting functions can reduce the failure frequency of wafer transportation due to a swaying motion or an irregular suspension. Based on the experiment result, a reduction of transportation failure can increase 33% wafer transport rate and decrease servicing time of 240 minutes, thereby increasing 25% wafer transport efficiency of semiconductor wafer fab in one day. Following will describe the detail structural features of the lifting device according to the figures of the instant disclosure.

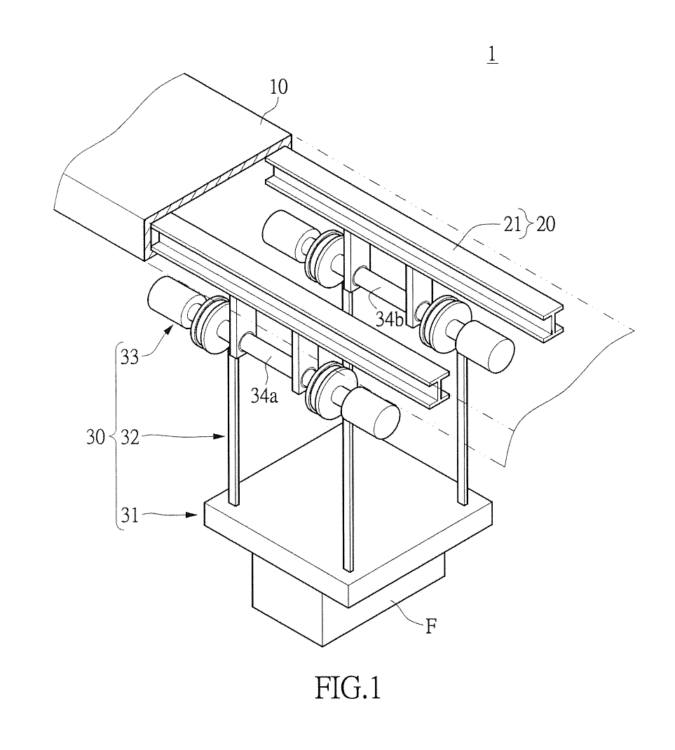

Please refer to FIG. 1, which shows a three-dimensional view of the automatic handling system according to the first embodiment of the instant disclosure. The automatic handling system 1 includes a suspension rail 10, at least one automatic guiding vehicle 20, and at least one lifting device 30. The suspension rail 10 is located on an overhead space of semiconductor wafer fab. The automatic guiding vehicle 20 is slidably coupled to the suspension rail 10, and the lifting device 30 is configured to connect the automatic guiding vehicle 20. Thus, the lifting device 30 can move along the suspension rail 10 and transport wafer carriers (FOUP) F containing a plurality of wafers between different load ports (not shown) of the same processing tool or between different processing tools (not shown) after completing a specific process.

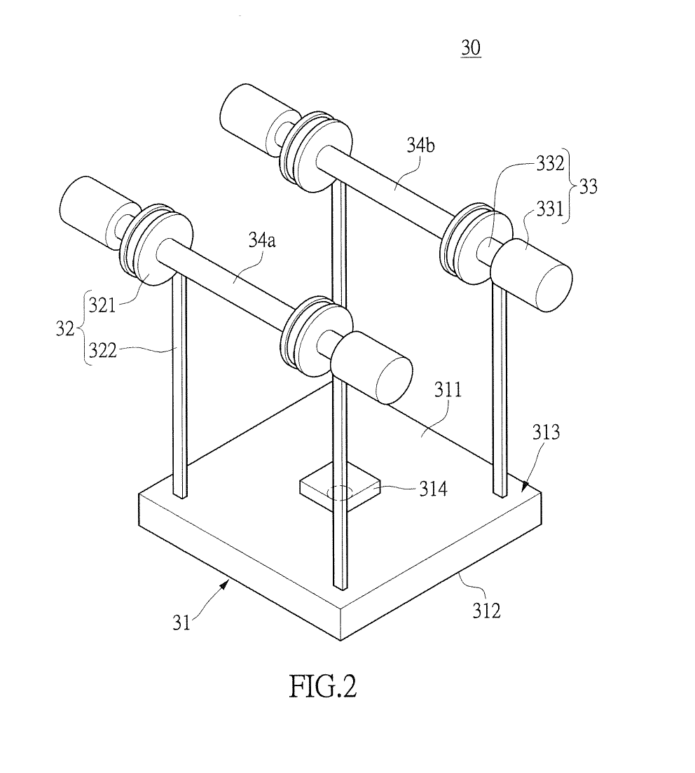

Please refer to FIG. 2, which shows a three-dimensional view of the lifting device according to the first embodiment of the instant disclosure. The lifting device 30 includes an elevating holder 31, a plurality of suspension modules 32 and a plurality of first drive modules 33. The elevating holder 31 has an upper portion 311 and a lower portion 312, arranged below the automatic guiding vehicle 20. The lower portion 312 is substantially shaped as a claw structure, but not limited thereto. The upper portion 311 is suspensively connected to the automatic guiding vehicle 20 by the suspension modules 32.

In a preferred embodiment, the automatic guiding vehicle 20 includes a pair of guide tracks 21 slidably coupled to the suspension rail 10. The lifting device 30 further includes a first positioning rod 34a and a second positioning rod 34b substantially parallel to the first positioning rod 34a, and the first and second positioning rods 34a, 34b are fixedly connected to the guide tracks 21 respectively. Moreover, two of the suspension modules 32 are arranged as a pair on the two opposite ends of the first positioning rod 34a, and the other two of the suspension modules 32 are arranged as a pair on the two opposite ends of the second positioning rod 34b. Further, the elevating holder 31 is a generally elongated structure having four corner regions 313, and the suspension modules 32 are connected to the corner regions 313 respectively to provide structural stability.

Concretely speaking, each of the suspension modules 32 includes a guide element 321 and a suspension element 322. The guide elements 321 are rotatably mounted on the opposite ends of the first and second positioning rods 34a, 34b, and each suspension element 322 abuts the corresponding guide element 321. In other words, the suspension elements 322 are operatively coupled to the guide elements 321 to elevate or lower the elevating holder 31. It is available that the guide elements 321 may each take any form including, but not limited to, gear wheel or belt wheel, etc., the suspension elements 322 may each take any form including, but not limited to, chain or timing belt, etc.

The first drive modules 33 are configured to connect the suspension modules 32, wherein the guide elements 321 can be driven by the first drive modules 33 for rotation, and the suspension elements 322 all cooperate with the guide elements 321 to activate the elevating holder 31 to transport the wafer carrier F. In a preferred embodiment, each of the first drive modules 33 includes a motor 331 and a drive shaft 332 coupled to the motor 331. The guide elements 321 are driven by the motors 331 via the drive shafts 332, wherein one end of the drive shafts 332 are connected to the motors 331, and the other end thereof are connected to the guide elements 321. It is available that the motors 331 may each take any form including, but not limited to, servo motor or stepper motor, etc.

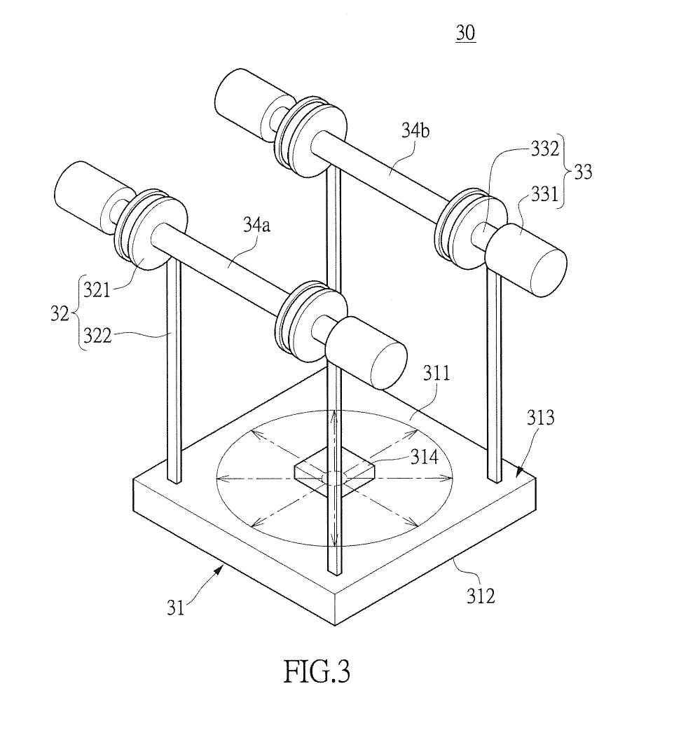

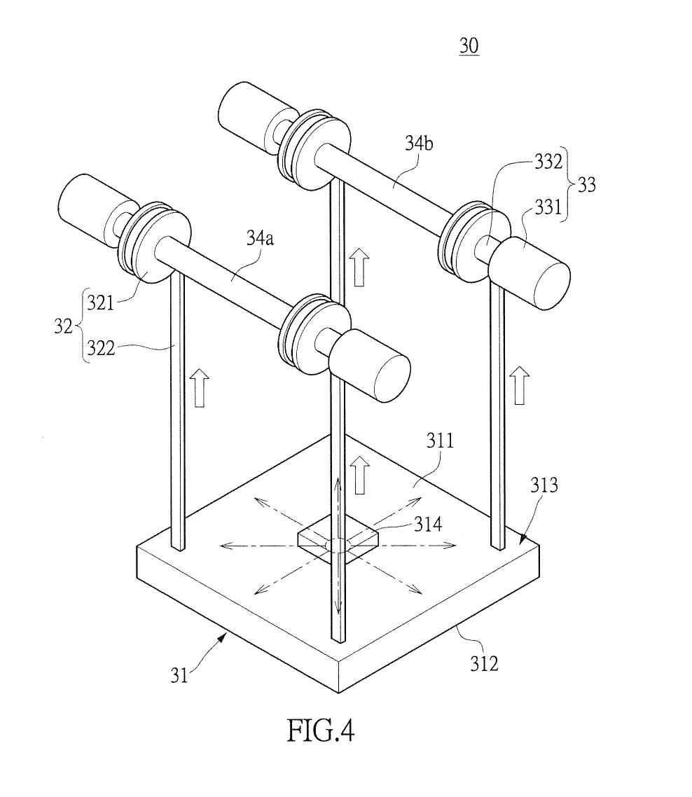

Referring to FIGS. 3 to 5, it is notable that the elevating holder 31 has a motion sensor 314 arranged thereon. Therefore, the motion sensor 314 can detect the change of the elevating holder 31 from horizontal to vertical position (as shown in FIG. 3) in a raising or lowering motion. In other words, the motion sensor 314 is configured to detect whether the elevating holder 31 is in a horizontal state or a non-horizontal state. It is available that the motors 331 may take any form including, but not limited to, gyroscope or g-sensor, etc.

Further, the motion sensor 314 is electrically connected to a processor (not shown) in actual application, please not that the processor can be arranged on the elevating holder 31 of the lifting device 30 or the automatic handling system 1. To synchronously drive the suspension modules 32, the processor sends a synchronization command to the motors 331 according to the horizontal state detected by the motion sensor 314, and then the suspension modules 32 elevate the elevating holder 31 with synchronous execution of the motors 331.

Otherwise, to individually drive the suspension modules 32, the processor sends a compensation command to the motors 331 according to the non-horizontal state detected by the motion sensor 314, and then the suspension modules 32 elevate the elevating holder 31 with asynchronous execution of the motors 331 to recover the elevating holder 30 from the non-horizontal state as the horizontal state, thereby improving the alignment accuracy of the elevating holder 30 with the wafer carrier (not shown).

Furthermore, said synchronous execution means that the first drive modules 33 synchronousively rotate the guide element 321 at same rotational speed. Thus, the raising/lowering speed of all connection points of the suspension elements 322 and the elevating holder 31 will be same. Said asynchronous execution means that the first drive modules 33 individually rotate the guide element 321 at different rotational speeds. Thus, the raising/lowering speed of some of the connection points of the suspension elements 322 and the elevating holder 31 may be different from the others.

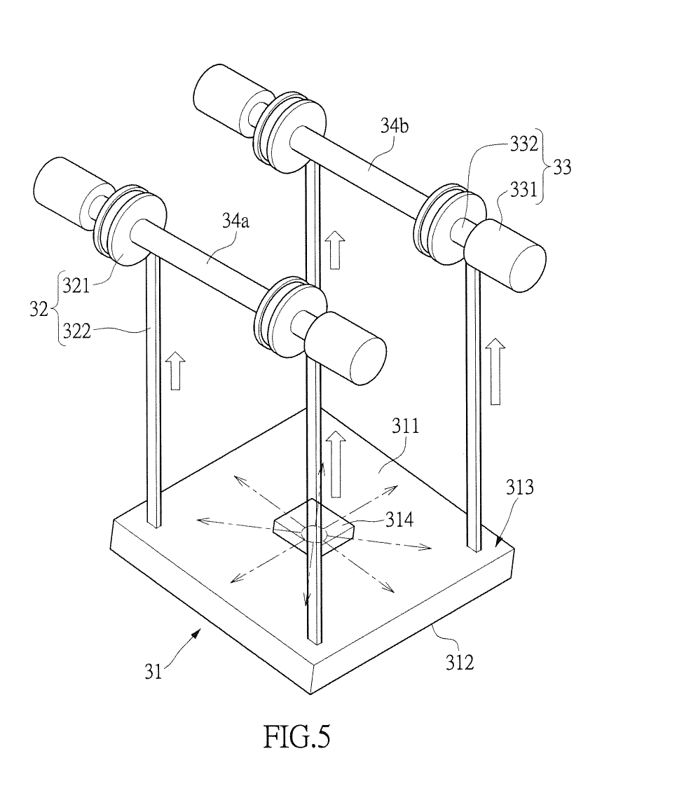

Referring to FIG. 5 again, this is used to illustrate the compensating action of the lifting device 30 under said asynchronous execution. For example, when the elevating holder 31 tilts toward the lower right, the right-side two of the first drive modules 33 can rotate the guide element 321 with a higher rotational speed than the left-side two of the first drive modules 33. In other words, the raising speed of the connection points of the right-side two of the suspension elements 322 and the elevating holder 31 are such higher than the left-side two that the elevating holder 31 can be recovered from the non-horizontal state as the horizontal state as the horizontal state. Therefore, the lifting device can prevent the automatic handling system 1 thereof from abnormal because of the non-horizontal state during the transporting procedures.

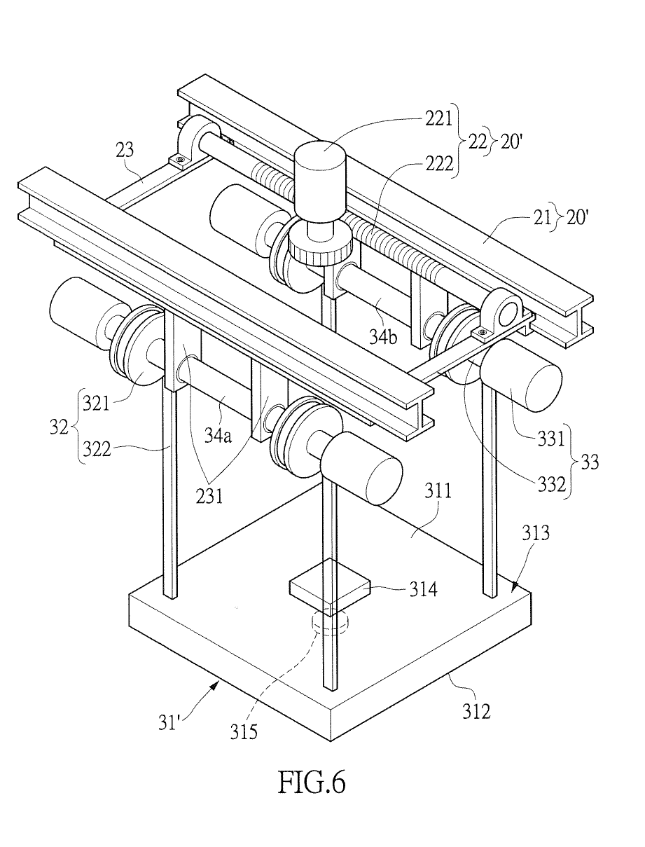

Please refer to FIG. 6, which shows a three-dimensional view of the lifting device according to the second embodiment of the instant disclosure. The difference of the lifting device 30 between the second embodiment and the first embodiment is described as follows. First, the automatic guiding vehicle 20′ includes a second drive module 22 and a sliding bracket 23, wherein the sliding bracket 23 is slidably coupled to the guide tracks 21, the second drive module 22 is configured to drive the sliding bracket 23 to move along a single axis, and the first positioning rod 34a and the second positioning rod 34b are fixedly connected with the sliding bracket 23. Moreover, the elevating holder 31′ further has a visual sensing element 315.

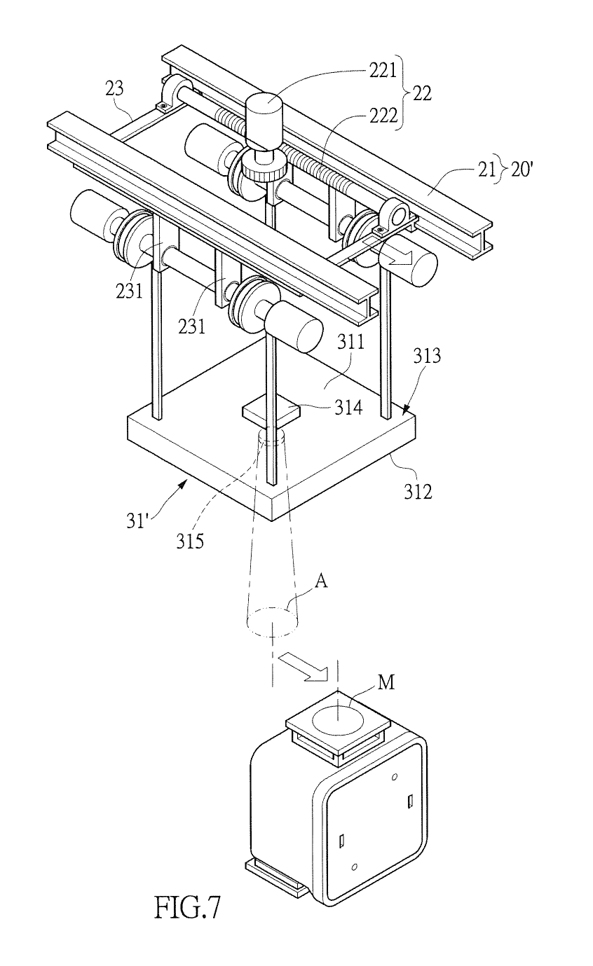

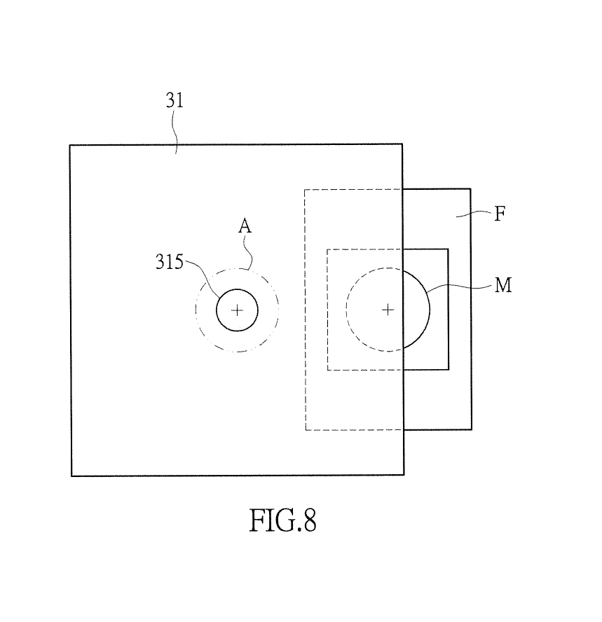

Referring to FIGS. 7 and 8, showing the alignment procedure of the elevating holder and the wafer carrier. In this embodiment, the wafer carrier F has a positioning marker M disposed on a top side thereof corresponding to the elevating holder 31′ for alignment by the visual sensing element 315. The second drive module 22 includes a driving element 221 and a linear bearing 222 operatively coupled to the driving element 221, and the two ends of the linear bearing 222 are fixedly connected to the sliding bracket 23. Thus, the driving element 221 of the second drive module 22 can drive the sliding bracket 23 with the lifting device 30 to reciprocately move along a single axis in correspondence with the wafer carrier F.

It is notable that wafer carriers F may be placed onto load ports of different processing tools according to various manufacturing process. Thus, the predetermined position of the lifting device 30 for aligning with each wafer carrier F may remain an error. Meanwhile, the controller of the automatic handling system 1 transmits an adjusting command such that the second drive module 22 drives the sliding seat 23 with the lifting device 30 to move toward the wafer carrier F until the positioning marker M of the wafer carrier F locates in a viewing defined by the visual sensing element 315. Further, the controller transmits a transporting command such that the elevating holder 31′ of the lifting device 30 grasps the wafer carrier F.

Base on above, the advantages of the instant disclosure with respect to traditional handling system of wafer fab is described below.

First, the lifting device utilizing the first drive modules to drive the suspension modules one to one by arranging the motion sensor together can achieve auto-horizontal adjusting function. Therefore, the lifting device can prevent the automatic handling system thereof from abnormal alarm due to the non-horizontal state during the transporting procedures.

Second, the lifting device can work operatively with a horizontal shift mechanism (including a sliding and a second drive module) and a visual sensing element, thereby has auto-horizontal positioning function. Thus, there is no need to calibrate the various processing tools such that the shutdown time and calibration time of the tools can be reduced, and the transporting efficiency of the automatic handling system can be improved.

Finally, the lifting device with the auto-horizontal positioning and auto-horizontal adjusting functions can further reduce the time of traffic jam when one automatic guiding vehicle down and the other automatic guiding vehicles are blocked.

The descriptions illustrated supra set forth simply the preferred embodiments of the instant disclosure; however, the characteristics of the instant disclosure are by no means restricted thereto. All changes, alternations, or modifications conveniently considered by those skilled in the art are deemed to be encompassed within the scope of the instant disclosure delineated by the following claims.

What is claimed is:

1. A lifting device for transporting a wafer carrier to an automatic handling system including a suspension rail and an automatic guiding vehicle configured to move along the suspension rail, the lifting device comprising:
an elevating holder arranged below the automatic guiding vehicle, having a motion sensor configured to detect whether the elevating holder is in a horizontal state or a non-horizontal state;
a plurality of suspension modules arranged on the automatic guiding vehicle for suspensively supporting the elevating holder; and
a plurality of first drive modules configured to connect the suspension modules respectively;
wherein the first drive modules being used to synchronously drive the suspension modules according the horizontal state detected by the motion sensor, and wherein the first drive modules being used to individually drive each of the suspension modules according the non-horizontal state detected by the motion sensor to recover the elevating holder from the non-horizontal state as the horizontal state.

2. The lifting device according to claim 1, further comprising a first positioning rod and a second positioning rod substantially parallel to the first positioning rod, the first positioning rod and the second positioning rod are arranged below the automatic guiding vehicle, two of the suspension modules are arranged as a pair on the two opposite ends of the first positioning rod, and the other two of the suspension modules are arranged as a pair on the two opposite ends of the second positioning rod in pair.

3. The lifting device according to claim 2, wherein each of the suspension modules comprises a guide element and a suspension element, the guide elements are rotatably mounted on the opposite ends of the first and second positioning rods, and each suspension element is operatively coupled to the corresponding guide element.

4. The lifting device according to claim 3, wherein each of the first drive modules comprises a motor and drive shaft coupled to the motor for rotation, the guide elements are driven by the motors via the drive shafts, and the suspension elements are cooperated with the guide elements to elevate the elevating holder.

5. An automatic handling system comprising:
a suspension rail and at least one automatic guiding vehicle configured to move along the suspension rail for transporting a wafer carrier between different processing tools; and
at least one lifting device configured to connect the automatic guiding vehicle, comprising:
an elevating holder arranged below the automatic guiding vehicle, having a motion sensor configured to detect whether the elevating holder is in a horizontal state or a non-horizontal state;
a plurality of suspension modules arranged on the automatic guiding vehicle for suspensively supporting the elevating holder; and
a plurality of first drive modules configured to connect the suspension modules respectively;
wherein the first drive modules being used to synchronously drive the suspension modules according the horizontal state detected by the motion sensor, and wherein the first drive modules being used to individually drive each of the suspension modules according the non-horizontal state detected by the motion sensor to recover the elevating holder from the non-horizontal state as the horizontal state.

6. The automatic handling system according to claim 5, wherein the lifting device comprises a first positioning rod and a second positioning rod substantially parallel to the first positioning rod, the first positioning rod and the second positioning rod are arranged below the automatic guiding vehicle, two of the suspension modules are arranged as a pair on the two opposite ends of the first positioning rod, and the other two of the suspension modules are arranged as a pair on the two opposite ends of the second positioning rod in pair.

7. The automatic handling system according to claim 6, wherein each of the suspension modules comprises a guide element and a suspension element, the guide elements are rotatably mounted on the opposite ends of the first and second positioning rods, and each suspension element is operatively coupled to the corresponding guide element.

8. The automatic handling system according to claim 7, wherein each of the first drive modules comprises a motor and drive shaft coupled to the motor for rotation, the guide elements are driven by the motors via the drive shafts, and the suspension elements are cooperated with the guide elements to elevate the elevating holder.

9. The automatic handling system according to claim 5, wherein the automatic guiding vehicle comprises a pair of guide tracks, a sliding bracket slidably coupled to the guide tracks, and a second drive module connected to the sliding bracket, the sliding bracket is configured in such a way that the first and second positioning rods are fixed thereto, and the lifting device are driven to move over the wafer carrier due to the single axial movement of the sliding bracket.

10. The automatic handling system according to claim 9, wherein the second drive module comprises a driving element and a linear bearing operatively coupled to the driving element, and the two ends of the linear bearing are fixed to the sliding bracket.

11. The automatic handling system according to claim 9, wherein the wafer carrier has a positioning marker disposed on a top side thereof, and the elevating holder further comprises a visual sensing element for capturing an image of the positioning marker.
